(19) United States
(12) Patent Application Publication
(10) Pub. No.: US 2025/0133882 A1
(43) Pub. Date: Apr. 24, 2025

(54) LIGHT EMITTING DEVICE

(71) Applicant: TOYODA GOSEI CO., LTD., Kiyosu-shi (JP)

(72) Inventors: Aya KAWAOKA, Kiyosu-shi (JP); Takeshi MATSUSHIMA, Kiyosu-shi (JP); Hisayuki MIKI, Kiyosu-shi (JP)

(21) Appl. No.: 18/912,170

(22) Filed: Oct. 10, 2024

(30) Foreign Application Priority Data
Oct. 20, 2023 (JP) 2023-181228

(51) Int. Cl. H01L 33/56; H01L 33/48; H01L 33/58

(52) U.S. Cl. CPC H10H 20/854; H10H 20/855; H10H 20/8506

(57) ABSTRACT

The light emitting device includes a mounting substrate, an ultraviolet light emitting element having a main surface facing opposite the mounting surface and a side surface, a light transmitting member forming a housing space for housing the light emitting element in a gap with the mounting surface of the mounting substrate, an inert compound being liquid at normal temperature and pressure filled in at least a main gap between the main surface of the light emitting element and the light transmitting member in a housing space, and a gas layer formed in a gap facing the side surface of the light emitting element in the housing space, wherein the inert compound has a contact angle of 10° to 30° with respect to the main surface of the light emitting element at a temperature of 25° C.

### CROSS-REFERENCE

This application claims priority to Japanese patent application no. 2023-181228 filed on Oct. 20, 2023, the contents of which are fully incorporated herein by reference.

### TECHNICAL FIELD

The present disclosure relates to a light emitting device.

### BACKGROUND ART

Light emitting devices using ultraviolet light emitting elements are used in various applications. As such light emitting devices, for example, JP-A-2016-127156 and JP-A-2022-108692 disclose a configuration in which an ultraviolet light emitting element is mounted on a mounting substrate and the ultraviolet light emitting side of the light emitting element is covered with a sealing material that transmits ultraviolet light by a dome-shaped light transmitting member.

In one configuration disclosed in JP-A-2016-127156, a space enclosed by a main surface of the light emitting element on the opposite side to the mounting substrate, a side surface of the light emitting and the inner surface of the light transmitting member is filled with a cured sealing material that transmits ultraviolet light. In another configuration disclosed in JP-A-2016-127156, a space enclosed by the main surface and the side surface of the light emitting element and the inner surface of the light transmitting member is filled with a liquid sealing material that transmits ultraviolet light.

In a configuration disclosed in JP-A-2022-108692, a fluorocarbon compound being liquid at normal temperature and pressure fills a gap between the top surface as the main surface of the light emitting element and the inner surface of the light transmitting member. Furthermore, an air layer is located between the entire side surface of the light emitting element and the inner surface of the light transmitting member.

### SUMMARY OF THE INVENTION

In one configuration disclosed in JP-A-2016-127156, when a cured sealing material is used, a stress may occur in the light emitting element as the sealing material cures. In the other configuration disclosed in JP-A-2016-127156, when a liquid sealing material fills a gap, the liquid sealing material may come into contact with a bonding material between the mounting substrate and the light transmitting member, thereby affecting a bonding force of the bonding material.

It is desirable to have a configuration in which an inert compound being liquid at normal temperature and pressure is placed in a main gap between the main surface of the light emitting element and the light transmitting member, and an gas layer is formed in a gap facing the side surface of the light emitting element, as disclosed in JP-A-2022-108692. In this configuration, the inert compound and the gas layer exist in a space formed by the mounting substrate, the light emitting element, and the light transmitting member. It is necessary to devise a way to hold the position of the inert compound. Therefore, it is necessary to devise especially an inert compound being liquid at normal temperature and pressure.

In view of this background, an object of the present disclosure is to provide a light emitting device having a configuration in which an inert compound being liquid at normal temperature and pressure is held in the main gap between the main surface of the light element and the light transmitting member, and a gas layer is formed in the gap facing the side surface of the light emitting element.

One aspect of the present disclosure is a light emitting device including:
a mounting substrate having a mounting surface;
an ultraviolet light emitting element disposed on the mounting surface of the mounting substrate and having a main surface facing opposite the mounting surface and a side surface adjacent to the main surface of the light emitting element;
a light transmitting member disposed on the mounting surface of the mounting substrate and forming a housing space for housing the light emitting element in a gap with the mounting surface of the mounting substrate;
an inert compound being liquid at normal temperature and pressure and filled in at least a main gap between the main surface of the light emitting element and the light transmitting member in the housing space; and
a gas layer formed in a gap facing the side surface of the light emitting element in the housing space, wherein
the inert compound has a contact angle of 10° to 30° with respect to the main surface of the light emitting element at a temperature of 25° C.

According to the above aspect, the inert compound has the contact angle of 10° to 30° with respect to the main surface of the light emitting element at a temperature of 25° C., thereby enabling a configuration in which the inert compound being liquid at normal temperature and pressure is held in the main gap between the main surface of the light emitting element and the light transmitting member, and a gas layer is formed in the gap facing the side surface of the light emitting element.

### BRIEF DESCRIPTION OF THE DRAWINGS

FIG. 1 is a cross-sectional view of a light emitting device in a plane perpendicular to a mounting substrate in a first embodiment;

FIG. 2 is a schematic cross-sectional view illustrating a configuration of the light emitting element in the first embodiment;

FIG. 3 is an enlarged cross-sectional view in a vicinity of a second sub gap in FIG. 1;

FIG. 4 is a flow chart explaining a method for manufacturing the light emitting device in the first embodiment;

FIG. 5 is a schematic view explaining the method for manufacturing the light emitting device in the first embodiment;

FIG. 6 is an enlarged cross-sectional enlarged view in a vicinity of a second sub gap in a second embodiment;

FIG. 7 is a cross-sectional view of a light emitting device in a plane perpendicular to a mounting substrate in a third embodiment; and

FIG. 8 is a cross-sectional view of a light emitting device in a plane perpendicular to a mounting substrate in a fourth embodiment.

### DETAILED DESCRIPTION OF PREFERRED EMBODIMENTS

The light emitting device includes: a mounting substrate having a mounting surface; an ultraviolet light emitting element disposed on the mounting surface of the mounting substrate and having a main surface facing opposite the mounting surface and a side surface adjacent to the main surface of the light emitting element; a light transmitting member disposed on the mounting surface of the mounting substrate and forming a housing space for housing the light emitting element in a gap with the mounting surface of the mounting substrate; an inert compound being liquid at normal temperature and pressure and filled in at least a main gap between the main surface of the light emitting element and the light transmitting member in the housing space; and a gas layer formed in a gap facing the side surface of the light emitting element in the housing space. The inert compound has a contact angle of 10° to 30° with respect to the main surface of the light emitting element at a temperature of 25° C.

In the above light emitting device, the inert compound may have a viscosity of 0.01 Pa·s to 50 Pa·s at a temperature of 25° C. The inert compound can have the contact angle with respect to the main surface of the light emitting element at a temperature of 25° C. in the above range.

The main surface of the light emitting element may have an arithmetic mean roughness Ra of 0.1 nm to 100,000 nm. The inert compound can have the contact angle with respect to the main surface of the light emitting element at a temperature of 25° C. in the above range.

The inert compound may be disposed in contact with at least a part of the side surface of the light emitting element in the housing space, and the inert compound may have a contact angle of 10° to 30° with respect to the side surface of the light emitting element at a temperature of 25° C. The inert compound can be held in contact with at least a part of the side surface of the light emitting element and can be configured to form the gas layer in the gap facing the side surface of the light emitting element.

The side surface of the light emitting element may have an arithmetic mean roughness Ra of 0.1 nm to 100,000 nm. The inert compound can have the contact angle with respect to the side surface of the light emitting element at a temperature of 25° C. in the above range.

The inert compound may have a boiling point of 150° C. or higher. The inert compound can be held in a desired position even when the temperature of the light emitting element rises during operation.

The light emitting element during operation may be configured to have a junction temperature of 150° C. or lower. The inert compound can be held in the desired position.

The inert compound may have a transmittance of 50% or more for ultraviolet light with an emission wavelength. An ultraviolet light extraction efficiency can be increased when the inert compound is disposed.

The inert compound may include a fluoride compound. The refractive index difference between the light emitting element and the inert compound can be reduced, and the refractive index difference between the light transmitting member and the inert compound can be reduced. Thus, the ultraviolet light extraction efficiency can be increased.

The light emitting element may constitute a flip chip type which outputs light from a back surface of an element substrate included in the light emitting element, and the main surface of the light emitting element may be located on the back surface with respect to a surface on which a semiconductor layer is formed of the element substrate. The inert compound being liquid at normal temperature and pressure can be held in the main gap between the main surface of the light emitting element and the light transmitting member.

The main gap may have a distance of 0.1 μm to 500 μm. The inert compound being liquid at normal temperature and pressure can be held in the main gap between the main surface of the light emitting element and the light transmitting member.

### First Embodiment

### 1. Configuration of Light Emitting Device 1

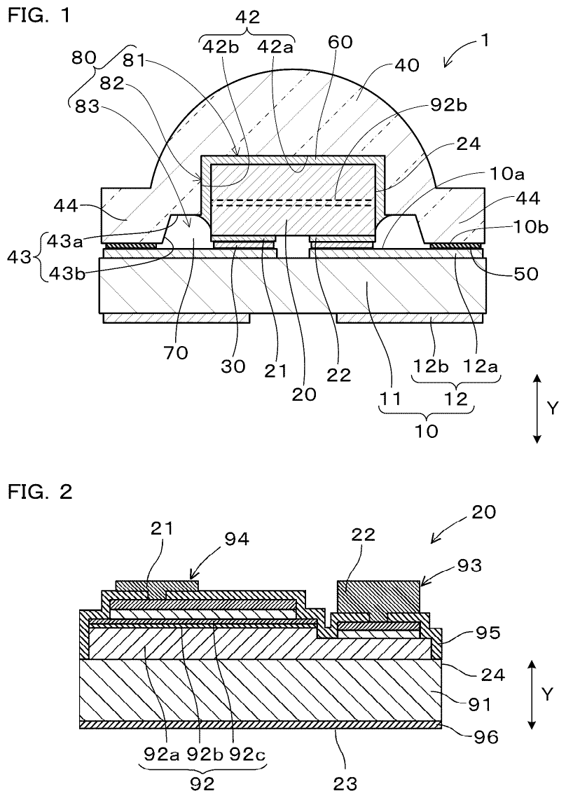

The configuration of the light emtting device 1 according to the first embodiment will be described with reference to FIG. 1. The light emitting device 1 constitutes a light emitting device package that houses an ultraviolet light emitting element 20 as a major component. The light emitting device 1 includes a mounting substrate 10, the light emitting element 20, an element bonding layer 30, a light transmitting member 40, a light transmitting member bonding layer 50, an inert compound 60, and a gas layer 70.

The mounting substrate 10 has a mounting surface 10a and constitutes a substrate for mounting the light emitting element 20 on the mounting surface 10a. In the first embodiment, the mounting substrate 10 has a flat plate shape. However, the mounting substrate 10 may have a case shape having a recess.

The mounting substrate 10 has a body part 11 and a circuit pattern 12. The body part 11 of the mounting substrate 10 has, for example, a flat plate shape. The body part 11 is formed, for example, of at least one ceramic selected from a group consisting of AlN, Al₂O₃, SiC, Si₂N₄, and the like. The circuit pattern 12 has a first pattern part 12a exposed on one side of the body part 11 of the mounting substrate 10, a second pattern part 12b exposed on the other side (bottom side in FIG. 1) of the body part 11 of the mounting substrate 10, and a connecting pattern part (not shown) connecting the first pattern part 12a and the second pattern part 12b. The surface on the first pattern part 12a side of the mounting substrate 10 constitutes the mounting surface 10a. The surface on the second pattern part 12b side of the mounting substrate 10 constitutes the surface exposed to the outside. The second pattern part 12b constitutes a portion electrically connected to an external mounting substrate (not shown).

The light emitting element 20 includes a group III nitride and emits ultraviolet light with a predetermined emission wavelength. The light emitting element 20 constitutes an ultraviolet light emitting element with an emission wavelength of 100 nm to 400 nm. In particular, the light emitting element 20 constitutes a deep ultraviolet light emitting element with an emission wavelength of 100 nm to 280 nm (UVC band). The light emitting element 20 has a thickness (vertical thickness in FIG. 1) of 1 μm or more. More specifically, the light emitting element 20 has the thickness of 400 μm to 1000 μm.

The light emitting element 20 is mounted on the mounting surface 10a of the mounting substrate 10. In the first embodiment, the light emitting element 20 constitutes a flip chip type element provided with electrode pads 21 and 22 on the mounting surface on the mounting substrate 10 side. Accordingly, the electrode pads 21 and 22 of the light emitting element 20 are disposed on the mounting surface 10a side of the mounting substrate 10 and are electrically connected to the first pattern part 12a of the circuit pattern 12 of the mounting substrate 10 via the element bonding layer 30. The light emitting element 20 is configured to have a junction temperature Tj of 150° C. or lower during operation, preferably 100° C. or lower.

In the first embodiment, the light emitting element 20 has a main surface 23 facing the opposite side (upper side in FIG. 1) of the mounting surface 10a of the mounting substrate 10 and a side surface 24 disposed in a circumferential direction and adjacent to the main surface 23. The main surface 23 has a planar shape parallel to the mounting surface 10a of the mounting substrate 10. The main surface 23 has a rectangular shape. The main surface 23 has an arithmetic mean roughness Ra of 0.1 nm to 100,000 nm.

The side surface 24 is adjacent to each of the outer edges of the main surface 23. The side surface 24 has a surface approximately perpendicular to the mounting surface 10a of the mounting substrate 10. In other words, the side surface 24 has four surfaces adjacent to each of the edges of the main surface 23. The side surface 24 has the arithmetic mean roughness Ra of 0.1 nm to 100,000 nm.

In the light emitting element 20, the angle formed by the main surface 23 and the side surface 24 is preferably in a range 80 to 100°, more preferably 90°, over the entire periphery of the main surface 23. The light emitting element 20 has a shape without chips, such as notches or dents, at the boundary between the main surface 23 and the side surface 24 across the entire periphery of the main surface 23.

The element bonding layer 30 bonds the first pattern part 12a of the circuit pattern 12 of the mounting substrate 10 to the electrode pads 21 and 22 of the light emitting element 20. The material of the element bonding layer 30 includes, for example, AuSn, Au, Ag, Cu, Al, or SAC.

The light transmitting member 40 is disposed on the mounting surface 10a side of the mounting substrate 10. More specifically, the light transmitting member 40 is bonded to the outer periphery of the mounting surface 10a of the mounting substrate 10 via the light transmitting member bonding layer 50. The light transmitting member 40 constitutes a sealing member for forming a housing space 80 in a gap opposing the mounting surface 10a of the mounting substrate 10. The housing space 80 houses the light emitting element 20 and the like.

The light transmitting member 40 may be made of a material that transmits ultraviolet light with an emission wavelength, and is made, for example, of glass. For example, the light transmitting member 40 is formed of at least one material selected from a group consisting of quartz, borosilicate, sapphire, fluoride, silicone resin, metaphosphate as examples of glass. When the light transmitting member 40 is made of quartz, the light transmitting member 40 has the refractive index of 1.45.

Here, the position where the light transmitting member 40 and the mounting substrate 10 are bonded (i.e., the position of the outer periphery 10b of the mounting substrate 10 to which the flange 44 of the light transmitting member 40 is bonded) is located closer to the mounting surface 10a of the mounting substrate 10 than the main surface of element 23 of the light emitting element 20 in a direction perpendicular to the mounting surface 10a of the mounting substrate 10. Furthermore, the position, where the light transmitting member 40 and the mounting substrate 10 are bonded, is located closer to the mounting surface 10a of the mounting substrate 10 than the active layer 92b of the light emitting element 20 in the direction perpendicular to the mounting surface 10a of the mounting substrate 10.

In the first embodiment, the position, where the light transmitting member 40 and the mounting substrate 10 are bonded, is located along the mounting surface 10a of the mounting substrate 10. The active layer 92b is disposed a distance away from the mounting surface 10a. With this configuration, as described above, the position, where the light transmitting member 40 and the mounting substrate 10 are bonded, is located closer to the mounting surface 10a of the mounting substrate 10 (bottom side in FIG. 1) than the active layer 92b of the light emitting element 20.

The light transmitting member 40 has, for example, a convex lens shape. That is, the outer surface of the light transmitting member 40 has a convex curved surface shape. By forming the light transmitting member 40 in a convex lens shape, the ultraviolet light emitted by the light emitting element 20 can be output mainly in a direction perpendicular to the mounting substrate 10.

The light transmitting member 40 is provided with a recess 41, which constitutes at least a part of the housing space 80, on a surface facing the mounting surface 10 a of the mounting substrate 10. The recess 41 is configured to house at least one portion of the light emitting element 20. In the first embodiment, the recess 41 is configured to house all of the light emitting elements 20. In other words, the housing space 80 is formed between the recess 41 of the light transmitting member 40 and the mounting surface 10a of the mounting substrate 10.

The recess 41 has a first recess 42 and a second recess 43. The recess 41 has a stepped shape with the first recess 42 and the second recess 43. The recess 41 may have a stepped shape with three or more steps.

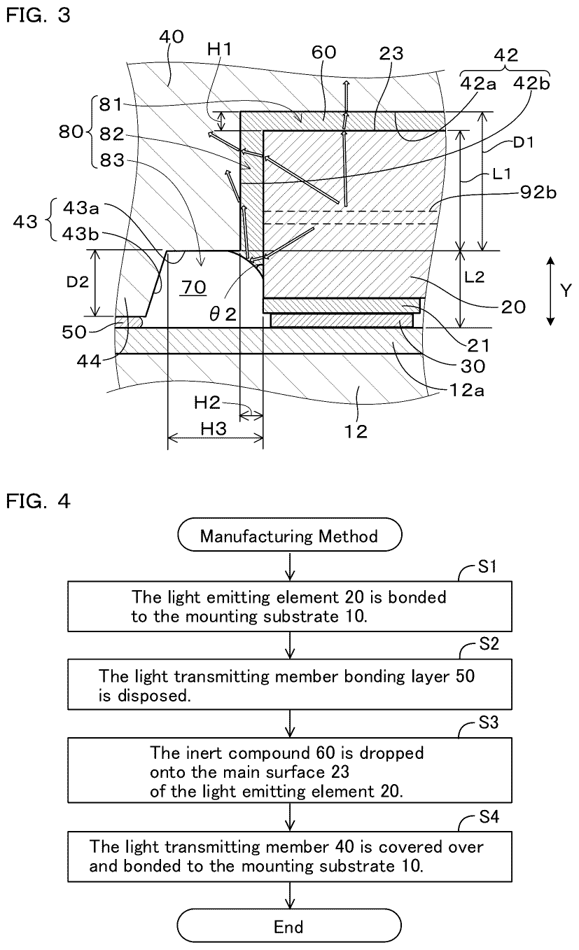

The first recess 42 is located in the center of the surface facing the mounting surface 10a of the mounting substrate 10 in the light transmitting member 40. The first recess 42 is configured to house one portion of the light emitting element 20. A depth of the first recess 42 is shorter than a height of the light emitting element 20. In the first embodiment, the depth of the first recess 42 is about half to two-thirds the thickness of the light emitting element 20. The first recess 42 shown in FIG. 3 has the depth D1 of 10 μm to 1,000 μm. The first recess 42 has a first ceiling surface 42a and a first side wall surface 42b.

The first ceiling surface 42a has a planar shape parallel to the mounting surface 10a of the mounting substrate 10. The first ceiling surface 42a has a rectangular shape. The first ceiling surface 42a is arranged to face the main surface 23 of the light emitting element 20. More specifically, the first ceiling surface 42a is formed parallel to the main surface 23 of the light emitting element 20 and is disposed at a predetermined distance away from the main surface 23. Thus, a main gap 81 is formed between the first ceiling surface 42a of the first recess 42 and the main surface 23 of the light emitting element 20.

The first side wall surface 42b is adjacent to each of the outer edges of the first ceiling surface 42a. The first side wall surface 42b has a surface that is approximately perpendicular to the mounting surface 10a of the mounting substrate 10. In other words, the first side wall surface 42b has four surfaces adjacent to each of the edges of the first ceiling surface 42a. Each surface of the first side wall surface 42b is formed parallel to a portion closer to the main surface 23 (upper portion in FIG. 1) of the side surface 24 of the light emitting element 20, and is disposed a predetermined distance away from the portion closer to the main surface 23 of the side surface 24. Thus, a first sub gap 82 is formed between the first side wall surface 42b of the first recess 42 and the portion closer to the main surface 23 (upper portion in FIG. 1) of the side surface 24 of the light emitting element 20.

The second recess 43 is disposed closer to the opening of the first recess 42, has an opening that is enlarged from the opening of the first recess 42, and has a shallower ceiling surface than the ceiling surface of the first recess 42. The second recess 43 is configured to house another portion of the light emitting element 20. A depth D2 of the second recess 43 is shorter than the height of the light emitting element 20. In the first embodiment, the depth D2 of the second recess 43 is about half the thickness of the light emitting element 20. The second recess 43 shown in FIG. 3 has the depth D2 of 10 μm to 1,000 μm. The second recess 43 has a second ceiling surface 43a and a second side wall surface 43b.

The second ceiling surface 43a has a planar shape parallel to the mounting surface 10a of the mounting substrate 10. The second ceiling surface 43a is adjacent to the first side wall surface 42b of the first recess 42. The outer periphery of the second ceiling surface 43a may be rectangular or circular. The second ceiling surface 43a has a ring shape. The second ceiling surface 43a is disposed facing the mounting surface 10a of the mounting substrate 10 and at a predetermined distance away from the mounting surface 10a.

The second side wall surface 43b is adjacent the outer periphery of the second ceiling surface 43a. The second side wall surface 43b is angled with respect to the mounting surface 10a of the mounting substrate 10. For example, the second side wall surface 43b forms an inclined surface having an acute angle with respect to the mounting surface 10a. The second side wall surface 43b is disposed facing the portion closer to the mounting substrate 10 (lower portion in FIG. 1) of the side surface 24 of the light emitting element 20 and at a predetermined distance away from the portion closer to the mounting substrate 10 of the side surface 24. Thus, a second sub gap 83 is formed between the second side wall surface 43b of the second recess 43 and the portion closer to the mounting substrate 10 (lower portion in FIG. 1) of the side surface 24 of the light emitting element 20.

The light transmitting member bonding layer 50 is disposed between the outer periphery 10b of the mounting surface 10a of the mounting substrate 10 and the flange 44 forming the outer periphery of the light transmitting member 40. The light transmitting member bonding layer 50 is formed of at least one selected from a group consisting of silicone resin, epoxy resin, fluororesin, solder, silane, glass, brazing material, and the like. In the first embodiment, the outer periphery 10b is disposed on the same plane as the mounting surface 10a.

As described above, the position, where the light transmitting member 40 and the mounting substrate 10 are bonded, is located closer to the mounting surface 10a of the mounting substrate 10 (lower side in FIG. 1) than the active layer 92b of the light emitting element 20 in the direction Y perpendicular to the mounting surface 10a of the mounting substrate 10. In other words, the light transmitting member bonding layer 50 is disposed closer to the mounting surface 10a of the mounting substrate 10 than the first sub gap 82. Furthermore, the light transmitting member bonding layer 50 is disposed closer to the mounting surface 10a of the mounting substrate 10 than the active layer 92b.

Even if the light transmitting member bonding layer 50 is formed of a material having not so high durability against ultraviolet light with an emission wavelength, the effect on the durability of the light transmitting member bonding layer 50 is extremely small. Therefore, the above inexpensive materials can be applied to the light transmitting member bonding layer 50. Needless to say, the light transmitting member bonding layer 50 may be formed of a material having high durability against ultraviolet light, for example, silicone resin.

The inert compound 60 is disposed in the housing space 80 surrounded by the mounting substrate 10 and the light transmitting member 40. The inert compound 60 is disposed in the main gap 81 and the first sub gap 82 of the housing space 80. In other words, the inert compound 60 is filled in the main gap 81 between the first ceiling surface 42a of the first recess 42 and the main surface 23 of the light emitting element 20. Thus, the inert compound 60 is in contact with the first ceiling surface 42a of the first recess 42 and the main surface 23 of the light emitting element 20.

Further, the inert compound 60 is filled in the first sub gap 82 between the first side wall surface 42b of the first recess 42 and the portion closer to the main surface 23 of the side surface 24 of the light emitting element 20. Thus, the inert compound 60 is in contact with the first side wall surface 42b of the first recess 42 and the portion closer to the main surface 23 of the side surface 24 of the light emitting element 20. The side surface of the active layer 92b of the light emitting element 20 faces the first sub gap 82. In other words, the side surface of the active layer 92b of the light emitting element 20 faces the inert compound 60.

The inert compound 60 is liquid at normal temperature and pressure. The inert compound 60 may be made of, for example, at least one selected from a group consisting of a fluoride compound, a silicon compound, a phosphate compound, and the like.

Fluoride compound as an example of the inert compound 60 is preferably, for example, to apply a carbon fluoride compound that is a polymer having C—F bonds. The number of carbon atoms in the carbon fluoride compound is 1.9 times or less the number of fluorine atoms in the carbon fluoride compound. Carbon fluoride compound apply, for example, perfluoropolyethers (PFPE) or hydrofluoroethers (HFE).

The gas layer 70 is disposed in the housing space 80 surrounded by the mounting substrate 10 and the light transmitting member 40. In the housing space 80, the light emitting element 20 and the inert compound 60 are disposed as described above. Accordingly, the gas layer 70 is disposed in at least a portion of the gap, excluding the position where the light emitting element 20 and the inert compound 60 are disposed of the housing space 80.

More specifically, the gas layer 70 is disposed in the second sub gap 83 of the housing space 80. In other words, the gas layer 70 is disposed in the second sub gap 83 between the second side wall surface 43b of the second recess 43 and the portion closer to the mounting substrate 10 of the side surface 24 of the light emitting element 20. That is, the gas layer 70 is in contact with the portion closer to the mounting substrate 10 of the side surface 24 of the light emitting element 20. Moreover, the gas layer 70 is in contact with a portion of the inert compound 60.

The gas layer 70 is formed, for example, at least one selected from a group consisting of air, nitrogen, carbon dioxide, and the like. The refractive index of the gas layer 70 is less than the refractive index of the inert compound 60. In the first embodiment, the gas layer 70 is formed by air, and the refractive index of air is 1.0.

### 2. Configuration of Light Emitting Element 20

The configuration of the light emitting element 20 will be described with reference to FIG. 2. FIG. 2 shows the configuration of the light emitting element 20 and is a cross-sectional view in a direction perpendicular to the main surface of the substrate. The light emitting element 20 of the first embodiment constitutes a flip chip type that outputs light from the back surface of the substrate (the side opposite to a main surface of the substrate). Therefore, the light emitting element 20 shown in FIG. 2 is an upside-down view of the light emitting element 20 shown in FIG. 1.

The light emitting element 20 mainly includes an element substrate 91, a semiconductor layer 92, an n-electrode 93, a p-electrode 94, a protective layer 95, and an anti-reflective layer 96. Since the light emitting element 20 constitutes the flip chip type, it has a structure to output light from the surface of the element substrate 91 (bottom surface in FIG. 2). The light emitting element 20 constitutes an ultraviolet light emitting element with an emission wavelength of 100 nm to 400 nm, particularly, a deep ultraviolet light emitting element with an emission wavelength of 100 nm to 280 nm (UVC band).

The element substrate 91 is formed, for example, of sapphire. The element substrate 91 may be formed of any material other than sapphire. The element substrate 91 may be formed of any material that has high transmittance with respect to the emission wavelength and is capable of growing a group III nitride semiconductor crystal. For example, the element substrate 91 may be formed of an AlN substrate or an AlN template substrate with an AlN layer formed on a sapphire substrate. If the element substrate 91 is formed of sapphire, the element substrate 91 has a refractive index of 1.76. The element substrate 91 has a thickness of 1 μm or more, preferably 100 μm or more.

The semiconductor layer 92 is formed on the main surface of the element substrate 91 by crystal growth. The semiconductor layer 92 is formed of a group III nitride semiconductor. The semiconductor layer 92 has at least an n-type layer 92a, an active layer 92b, and a p-type layer 92c. The semiconductor layer 92 is formed by depositing the n-type layer 92a, the active layer 92b, and the p-type layer 92c, in this order on the element substrate 91.

The n-type layer 92a contains a group III nitride semiconductor. The n-type layer 92a is formed, for example, of n-AlGaN. The active layer 92b contains a group III nitride semiconductor. The active layer 92b has an SQW structure in which a barrier layer, a well layer, and a barrier layer are deposited in this order on the n-type layer 92a. The active layer 92b may have an MQW structure. The well layer contains AlGaN, and the Al composition is set according to the desired emission wavelength. The barrier layer contains AlGaN having an Al composition higher than the Al composition of the well layer, and the barrier layer has the Al composition of 50% to 100%. The p-type layer 92c is also referred to a p-type contact layer because it constitutes a layer in contact with the electrode. The p-type layer 92c contains a group III nitride semiconductor. The p-type layer 92c may contain Mg-doped p-GaN, or p-AlGaN.

The n-electrode 93 is disposed on and in contact with the n-type layer 92a. The n-electrode pad 21 constituting the n-electrode 93 is exposed. The n-electrode pad 21 is disposed in contact with the first pattern 12a of the circuit pattern 12 of the mounting substrate 10, as shown in FIG. 1. The p-electrode pad 94 is disposed on and in contact with the p-type layer 92c. The p-electrode 94 includes a reflective layer that reflects ultraviolet light with an emission wavelength. Further, the p-electrode pad 22 constituting the p-electrode 94 is exposed. The p-electrode pad 22 is disposed in contact with the first pattern portion 12a of the circuit pattern 12 of the mounting substrate 10, as shown in FIG. 1.

The protective layer 95 is formed of an insulating material and protects the top and side surfaces of the semiconductor layer 92. A part of the n-electrode 93 is exposed and disposed on the protective layer 95. The n-electrode 93 is electrically connected to the n-type layer 92a through a hole of the protective layer 95. A part of the p-electrode 94 is exposed and disposed on the protective layer 95. The p-electrode 94 is electrically connected to the p-type layer 92c through a hole of the protective layer 95.

The anti-reflective layer 96 is disposed on the back surface of the element substrate 91 (bottom surface in FIG. 2, light output surface), and the surface of the anti-reflective layer 96 constitutes the main surface 23 of the light emitting element 20. However, the anti-reflective layer 96 may not be formed. In this case, the back surface of the element substrate 91 is exposed and constitutes the main surface 23 of the light emitting element 20.

### 3. Detailed Description of Gaps 81 to 83

The details of the main gap 81, the first sub gap 82, and the second sub gap 83 will be described with reference to FIG. 3. The main gap 81 is formed between the first ceiling surface 42a of the first recess 42 and the main surface 23 of the light emitting element 20. The main gap 81 has a distance H1 of 0.1 μm to 500 μm, preferably 0.1 um to 100 μm.

The first sub gap 82 is formed between the first side wall surface 42b of the first recess 42 and the portion closer to the main surface 23 (upper portion in FIG. 3) of the side surface 24 of the light emitting element 20. The distance H2 of the first sub gap 82 is longer than the distance H1 of the main gap 81. The first sub gap 82 has the distance H2 of 0.1 μm to 500 μm, preferably 0.1 μm to 100 μm. In the first embodiment, the first sub gap 82 faces the side surface of the active layer 92b of the light emitting element 20. However, the side surface of the active layer 92b of the light emitting element 20 is not exposed because it is covered with an insulating layer. Thus, the side surface of the active layer 92b of the light emitting element 20 faces the first sub gap 82 through the insulating layer.

The second sub gap 83 is formed between the second side wall surface 43b of the second recess 43 and the portion closer to the mounting substrate 10 (lower portion in FIG, 3) of the side surface 24 of the light emitting element 20. The minimum value of the distance H3 of the second sub gap 83 is longer than the distance H2 of the first sub gap 82. For example, the minimum value of the distance H3 of the second sub gap 83 is twice or more the distance H2 of the first sub gap 82. The second sub gap 83 has the distance H3 of 0.1 μm to 1,000 μm, preferably 50 μm to 500 μm.

As shown in FIG. 3, the length LI of the first sub gap 82 in the direction Y perpendicular to the mounting surface 10a of the mounting substrate 10 is longer than the length L2 of the second sub gap 83 in the direction Y.

### 4. Details of Inert Compound 60

The inert compound 60 contains, for example, at least one selected from a group consisting of a fluoride compound, a silicon compound, a phosphate compound, and the like. The inert compound 60 has a viscosity of 0.01 Pa·s to 50 Pa·s, preferably 0.1 Pa·s to 50 Pa·s, more preferably 1 Pa·s to 50 Pa·s.

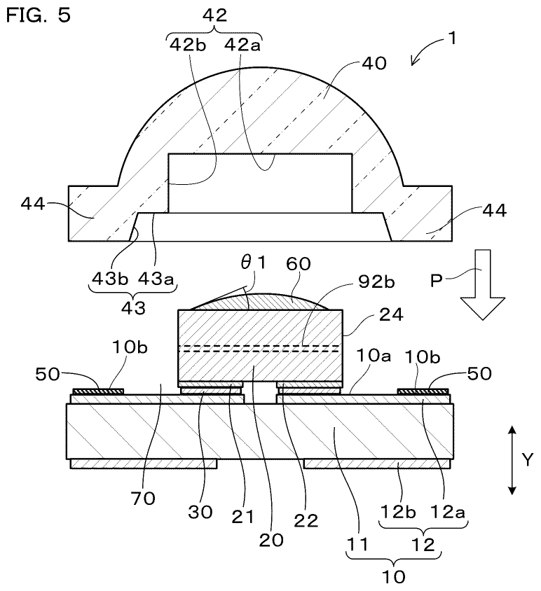

The inert compound 60 has a contact angle θ1 (shown in FIGS. 5) of 10° to 30°, preferably 17° to 23°, and more preferably 20° with respect to the main surface 23 of the light emitting element 20 at a temperature of 25° C. Thus, the inert compound 60 is held in the main gap 81 by capillary action. The inert compound 60 has a contact angle θ2 (shown in FIGS. 3) of 10° to 30°, preferably 17° to 23°, and more preferably 20° with respect to the side surface 24 of the light emitting element 20 at a temperature of 25° C. The inert compound 60 is held in the first sub gap 82 by capillary action.

In particular, the main surface 23 and the side surface 24 of the light emitting element 20 have arithmetic mean roughness Ra of 0.1 nm to 100,000 nm. Thus, the inert compound 60 is held in the main gap 81 and the first sub gap 82 by capillary action. Furthermore, the light emitting element 20 has a shape without chips, such as notches or dents, at the boundary between the main surface 23 and the side surface 24 across the entire periphery of the main surface 23. Thus, the inert compound 60 is held in the main gap 81 and the first sub gap 82.

The inert compound 60 has a boiling point of 150° C. or higher, preferably 200° C. or higher. The light emitting element 20 has a junction temperature Tj of 150° C. or lower, preferably 100° C. or lower during operation. In particular, the boiling point of the inert compound 60 is higher by 50° C., preferably by 100° C. than the junction temperature Tj of the light emitting element 20 during operation. Thus, even if the temperature of the light emitting element 20 rises, the inert compound 60 can be prevented from vaporizing and can be kept being held in the main gap 81 and the first sub gap 82 by capillary action.

The inert compound 60 has a transmittance of 50% or more, preferably 80% or more, for ultraviolet light with an emission wavelength of 280 nm. Furthermore, the refractive index of the inert compound 60 is closer to the refractive index of the light transmitting member 40 than to the refractive index of air. The refractive index of the inert compound 60 is closer to the refractive index of the element substrate 91 (shown in FIG. 2) of the light emitting element 20 than to the refractive index of air. In the first embodiment, the refractive index of the inert compound 60 may be larger than the refractive index of air and equal to or less than the refractive index of the light transmitting member 40 and the refractive index of the element substrate 91. If the inert compound 60 is formed of a carbon fluoride compound, the carbon fluoride compound has the refractive index of, for example, 1.2 to 1.6.

### 5. Boundary Shape Between Inert Compound 60 and Gas Layer 70

The boundary shape between the inert compound 60 and the gas layer 70 is described with reference to FIG. 3. In the first embodiment, the inert compound 60 is filled in the main gap 81 and the first sub gap 82. In addition, a part of the inert compound 60 slightly enters the second sub gap 83 through an opening of the first sub gap 82. Thus, the boundary between the inert compound 60 and the gas layer 70 is located in the second sub gap 83.

The boundary shape depends on the viscosity and contact angles θ1 and θ2 of the inert compound 60. In the first embodiment, at the boundary, the inert compound 60 has a predetermined angle with respect to the side surface 24 of the light emitting element 20. The predetermined angle depends on the contact angle θ2 of the inert compound 60 with respect to the side surface 24 and the contact angle of the inert compound 60 with respect to the second ceiling surface 43a. For example, a minimum value of the predetermined angle is the contact angle θ2 of the inert compound 60 with respect to the side surface of element 24 or the contact angle of the inert compound 60 with respect to the second ceiling surface 43a, and a maximum value of the predetermined angle is 45°.

The boundary functions as a reflector due to the refractive index difference between the inert compound 60 and the gas layer 70. In other words, a reflector having a predetermined angle is formed on the side surface 24 of the light emitting element 20. The reflectance at the boundary for ultraviolet light with an emission wavelength is, for example, 50% to 100%.

Here, the minimum value of the distance H3 of the second sub gap 83 is twice or more the distance H2 of the first sub gap 82. In this way, the boundary between the inert compound 60 and the gas layer 70 is located sufficiently far from the light transmitting member bonding layer 50. Thus, the inert compound 60 is suppressed from flowing to the position of the light transmitting member bonding layer 50.

### 6. Path of Ultraviolet Light

The path of the ultraviolet light emitted by the light emitting element 20 is described with reference to FIG. 3. The ultraviolet light emitted by the active layer 92b of the light emitting element 20 is output from the main surface 23 of the light emitting element 20. The main gap 81 is filled with the inert compound 60. Accordingly, the light transmitting member 40 is disposed through the inert compound 60 above the main surface 23. The emitted ultraviolet light enters the light transmitting member 40 through the inert compound 60 from the main surface 23 and is then output from the light transmitting member 40 to the outside.

Here, the inert compound 60 is in contact with the main surface 23, and is also in contact with the first ceiling surface 42a of the first recess 42 of the light transmitting member 40. Accordingly, the emitted ultraviolet light is suppressed from being reflected by the main surface 23 and is output from the light transmitting member 40.

The ultraviolet light emitted by the active layer 92b of the light emitting element 20 is also output from the side surface 24 of the light emitting element 20. The first sub gap 82 is filled with the inert compound 60. The emitted ultraviolet light is output from the light transmitting member 40 through the inert compound 60 in the first sub gap 82 from the portion closer to the main surface 23 of the side surface 24.

Here, the inert compound 60 is in contact with the portion closer to the main surface 23 of the side surface 24, and is also in contact with the first side wall surface 42b of the first recess 42 of the light transmitting member 40. Accordingly, the emitted ultraviolet light is suppressed from being reflected at the side surface 24 of the light emitting element 20 and is output from the light transmitting member 40.

Furthermore, a part of the ultraviolet light output from the side surface of element 24 is directed toward the boundary between the inert compound 60 and the gas layer 70. In the first embodiment, a part of the ultraviolet light emitted from the active layer 92b to the mounting substrate 10 is directed toward the boundary between the inert compound 60 and the gas layer 70.

At the boundary between the inert compound 60 and the gas layer 70, the ultraviolet light is reflected. Therefore, a part of the ultraviolet light output from the side surface 24 is reflected at the boundary and travels to the light transmitting member 40. The ultraviolet light is then output from the light transmitting member 40 to the outside.

A part of the ultraviolet light emitted by the active layer 92b is transmitted through the boundary between the inert compound 60 and the gas layer 70. However, extremely less ultraviolet light is transmitted from the inert compound 60 to the gas layer 70. Furthermore, a part of the ultraviolet light emitted by the active layer 92b is output to the gas layer 70 from the portion in contact with the gas layer 70 of the side surface 24. However, extremely less ultraviolet light is output to the gas layer 70. Therefore, even if the light transmitting member bonding layer 50 is formed of a material having high durability against ultraviolet light, such as silicone resin, the effect on the durability of the light transmitting member bonding layer 50 is extremely small. Accordingly, the above inexpensive materials can be applied to the light transmitting member bonding layer 50.

### 7. Method for Manufacturing Light Emitting Device 1

The method for manufacturing a light emitting device 1 is described with reference to FIG. 4 and FIG. 5. In a step S1 shown in FIG. 4, the light emitting element 20 is bonded to the mounting surface 10a of the mounting substrate 10. Then, in a step S2, the light transmitting member bonding layer 50 is placed on the mounting surface 10a of the mounting substrate 10 or the bonding surface of the flange 44 of the light transmitting member 40.

Then, in a step S3, the inert compound 60 is dropped onto the main surface 23 of the light emitting element 20. At this time, as shown in FIG. 5, the inert compound 60 stays on the main surface 23 of the light emitting element 20 due to surface tension. The volume of the inert compound 60 being dropped is almost the same as the total volume of the main gap 81 and the first sub gap 82. More specifically, the volume of the inert compound 60 being dropped is slightly larger than the total volume of the main gap 81 and the first sub gap 82. The volume of the inert compound 60 being dropped is sufficiently less than the total volume of the main gap 81, the first sub gap 82 and the second sub gap 83.

As mentioned above, at a temperature of 25° C., the contact angle θ1 of the inert compound 60 dropped onto the main surface 23 is 10° to 30°, preferably 17° to 23°, and more preferably 20°. Thus, the inert compound 60 stays in a thin thickness state on the main surface 23.

Subsequently, in a step S4 shown in FIG. 4, the light transmitting member 40 is covered over and bonded to the mounting substrate 10, as indicated by an arrow Pin FIG. 5. At this time, as the main surface 23 and the first ceiling surface 42a of the first recess 42 of the light transmitting member 40 come closer to each other, the inert compound 60 dropped onto the main surface 23 contacts the first ceiling surface 42a. Then, the inert compound 60 gradually moves toward the side surface 24. The inert compound 60 moved to the side surface 24 is held in the first sub gap 82 by capillary action between the side surface 24 and the first side wall surface 42b of the first recess 42 of the light transmitting member 40. Thus, the light emitting device 1 shown in FIG. 1 is manufactured.

In particular, when the contact angle θ1 of the inert compound 60 dropped on the main surface 23 at a temperature of 25° C. is within the above angle range, the inert compound 60 is held in the main gap 81 having the distance H1. Furthermore, when the contact angle θ2 of the inert compound 60 with respect to the side surface 24 at a temperature of 25° C. is within the above angular range, the inert compound 60 can be held in the first sub gap 82 having the distance H2.

### 8. Operation and Effect

Next, the operation and effect in the light emitting device according to the first embodiment are described in detail. According to the light emitting device of the first embodiment, the inert compound 60 being liquid at normal temperature and pressure, is filled into the main gap 81 between the main surface 23 and the first ceiling surface 42a of the recess 41 of the light transmitting member 40, and into the first sub gap 82 between the portion closer to the main surface 23 of the main surface 24 and the first side wall surface 42b of the recess 41 of the light transmitting member 40.

Furthermore, the gas layer 70 is formed in the second sub gap 83 facing the portion closer to the mounting substrate 10 of the side surface 24. This prevents capillary action in the second sub gap 83 by the gas layer 70 formed in the second sub gap 83. As a result, the liquid inert compound 60 filled in the main gap 81 and the first sub gap 82 is preventing from flowing out and is held in the main gap 81 and the first sub gap 82. A decrease in the light extraction efficiency of the ultraviolet light emitted from the main surface 23 can be prevented. Furthermore, the light extraction efficiency of the ultraviolet light emitted from at least the portion closer to the main surface 23 of the side surface 24 can be improved. The light extraction efficiency of the light emitting device 1 can be improved.

In the first embodiment, the distance H3 of the second sub gap 83 is longer than the distance H2 of the first sub gap 82. Thus, the inert compound 60 is easily held in the main gap 81 and the first sub gap 82. Furthermore, the inert compound 60 is prevented from flowing into the second sub gap 83. As a result, the ultraviolet light extraction efficiency of the light emitting device 1 can be further improved.

In the first embodiment, the inert compound 60 is held in the main gap 81 and the first sub gap 82 by capillary action. Thus, the holding force of the inert compound 60 in the main gap 81 and the first sub gap 82 can be improved. Furthermore, the inert compound 60 filled in the main gap 81 and the first sub gap 82 can be prevented from flowing into the second gap 83. As a result, the ultraviolet light extraction efficiency of the light emitting device 1 can be further improved.

In the first embodiment, the distance H2 of the first sub gap 82 is longer than the distance H1 of the main gap 81. Thus, the holding force of the inert compound 60 in the main gap 81 by capillary action is further increased, and the inert compound 60 can be further prevented from flowing out into the second sub gap 83. As a result, the ultraviolet light extraction efficiency of the light emitting device 1 can be further improved.

In the first embodiment, the distance H1 of the main gap 81 is 0.1 μm to 500 μm, and the distance H2 of the first sub gap 82 is 0.1 μm to 500 μm. Thus, capillary action in the main gap 81 and the first sub gap 82 can be generated to promote prevention of the inert compound 60 from flowing into the second sub gap 83. As a result, the ultraviolet light extraction efficiency of the light emitting device 1 can be further improved.

In the first embodiment, the surface for forming the first sub gap 82 of the side surface 24 of the light emitting element 20 has an arithmetic mean roughness Ra of 100 μm or less. This decreases the contact angle of the inert compound 60 with respect to the side surface 24. As a result, the inert compound 60 can be more easily held in the first sub gap 82 by capillary action.

In the first embodiment, the light emitting element 20 has a shape without chips at the boundary between the main surface 23 and the side surface 24. This further prevents the inert compound 60 held in the main gap 81 and the first sub gap 82 from flowing into the second sub gap 83.

In the first embodiment, the side surface 24 of the light emitting element 20 and the first side wall surface 42b of the recess 41 are formed parallel to each other. This prevents the inert compound 60 held in the main gap 81 and the first sub gap 82 from flowing into the second sub gap 83.

In the first embodiment, the side surface of the active layer 92b of the light emitting element 20 faces the first sub gap 82 and faces the inert compound 60.

Therefore, the ultraviolet light emitted from the side surface of the active layer 92b enters the light transmitting member 40 through the inert compound 60. The ultraviolet light incident on the light transmitting member 40 passes through the light transmitting member 40 and is subsequently output from the light transmitting member 40. In this case, the ultraviolet light emitted from the side surface of the active layer 92b is more likely to be output from the light transmitting member 40 than when the side surface of the active layer 92b faces the gas layer 70. As a result, the ultraviolet light extraction efficiency of the light-emitting device 1 can be further improved.

In the first embodiment, the length L1 in the direction Y perpendicular to the mounting surface 10a of the mounting substrate 10 of the first sub gap 82 is longer than the length L2 in the direction Y of the second sub gap 83. Thus, the ultraviolet light emitted from the side surface of active layer 92b of the light emitting element 20 is more easily output from light transmitting member 40 through the inert compound 60. As a result, the ultraviolet light extraction efficiency of the light emitting device can be further improved.

In first embodiment, the inert compound 60 is held in the main gap 81 and the first sub gap 82 as described above, so that the contact angle θ1 of the inert compound 60 with respect to the main surface 23 at a temperature of 25° C. is 10° to 30°. Thus, the inert compound 60 being liquid at normal temperature and pressure is held in the main gap 81 between the main surface 23 of the light emitting element 20 and the light transmitting member 40. Furthermore, the gas layer 70 is formed in the gap facing the side surface 24 of the light emitting element 20.

In the first embodiment, the viscosity of the inert compound 60 at a temperature of 25° C. is 0.01 Pa·s to 50 Pa·s. Thus, the contact angle θ1 of the inert compound 60 with respect to the main surface 23 at a temperature of 25° C. can be within the above range. Further, when the arithmetic mean roughness Ra of the main surface of element 23 is 0.1 nm to 100,000 nm, the contact angle θ1 of the inert compound 60 with respect to the main surface 23 at a temperature of 25° C. can be within the above range.

In the first embodiment, the inert compound 60 is disposed in contact with at least a portion of the side surface 24 of the light emitting element 20 in the housing space 80. Further, the contact angle θ2 of the inert compound 60 with respect to the side surface 24 at a temperature of 25° C. is 10° to 30°. Thus, the inert compound 60 is held in contact with at least a portion of the side surface 24 of the light emitting element 20. Furthermore, the gas layer 70 is formed in the gap facing the side surface of element 24. Further, when the arithmetic mean roughness Ra of the element side surface 24 is 0.1 nm to 100000 nm. Thus, the contact angle θ2 of the inert compound 60 with respect to the side surface 24 at a temperature of 25° C. can be within the above range.

In the first embodiment, the boiling point of the inert compound 60 is 150° C. or higher. The junction temperature of the light emitting element during operation is configured to be 150° C. or lower. Thus, the inert compound 60 can be held in the desired position even when the temperature of the light emitting element 20 rises during operation.

In the first embodiment, the inert compound 60 has a transmittance of 50% or less of ultraviolet light with an emission wavelength, thereby increasing the ultraviolet light extraction efficiency when the inert compound 60 is disposed. Furthermore, when the inert compound 60 is a fluoride compound, the refractive index difference between the light emitting element 20 and the inert compound 60 and between the light transmitting member 40 and the inert compound 60 can be reduced. Thus, the ultraviolet light extraction efficiency can be increased.

The light emitting element 20 constitutes the flip chip type that outputs light from the back surface of the element substrate 91 included in the light emitting element 20, and the main surface is located on the back surface with respect to the surface on which the semiconductor layer is formed of the element substrate. Thus, the inert compound 60 being liquid at normal temperature and pressure can be held in the main gap 81 between the main surface 23 of the light emitting element 20 and the light transmitting member 40. In particular, the distance H1 of the main gap 81 is 0.1 μm to 500 μm. Thus, the inert compound 60 being liquid at normal temperature and pressure can be held in the main gap 81 between the main surface 23 of the light emitting element 20 and the light transmitting member 40.

### Second Embodiment

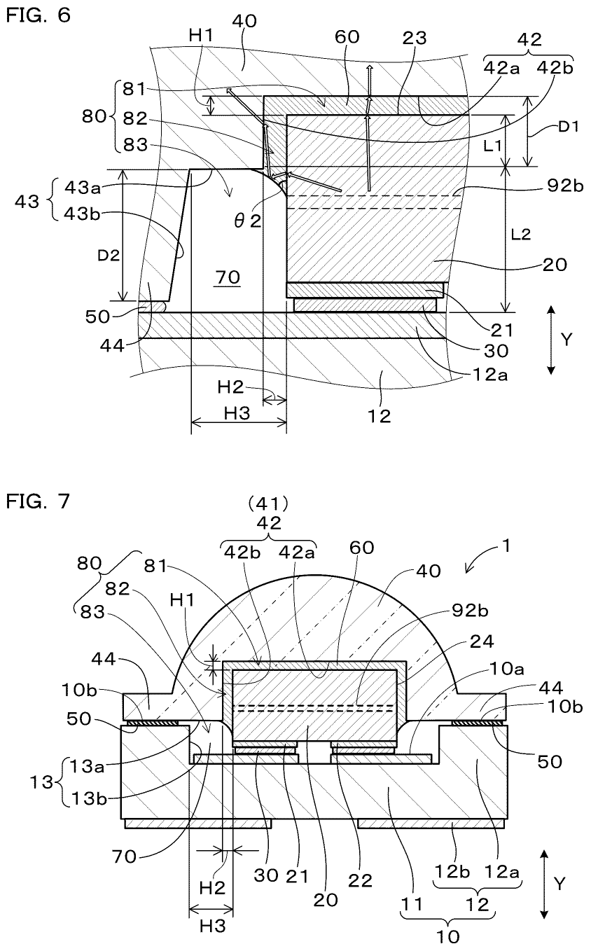

In the first embodiment, as shown in FIG. 3, the first sub gap 82 faces the side surface of the active layer 92b of light emitting element 20. Instead, in the second embodiment shown in FIG. 6, the first sub gap 82 does not face the side surface of the active layer 92b of the light emitting element 20, and the second sub gap 83 may face the side surface of the active layer 92b of the light emitting element 20. In the second embodiment, same symbols are given to the configuration corresponding to that of the first embodiment, and repeated explanation is omitted.

Even in the second embodiment, a portion of the ultraviolet light emitted by the active layer 92b of the light emitting element 20 enters the inert compound 60 of the first sub gap 82 from the side surface 24 facing the first sub gap 82 of the light emitting element 20. The ultraviolet light is then reflected by the boundary between the inert compound 60 and the gas layer 70 toward the light transmitting member 40. The ultraviolet light enters the light transmitting member 40 and is output from the light transmitting member 40 to the outside.

According to the second embodiment, the ultraviolet light directly emitted from the side surface of the active layer 92b to the gas layer 70 in the second sub gap 83 tends to increase compared to the first embodiment. Therefore, in the second embodiment, the degree of improvement in the ultraviolet light extraction efficiency of the light emitting device 1 is reduced compared to the first embodiment. However, needless to say, the ultraviolet light extraction efficiency is further improved compared to the case where the inert compound 60 is not present in the first sub gap 82. Except for the decrease in the degree of improvement of the ultraviolet light extraction efficiency, in the second embodiment, the same operation and effect are obtained as in the first embodiment.

### Third Embodiment

In the first embodiment above, as shown in FIG. 1, the outer periphery 10b, which is the junction with the flange 44 of the light transmitting member 40 in the mounting substrate 10, is located on the same plane as the mounting surface 10a. However, the present disclosure is not limited to this embodiment. As shown in the third embodiment shown in FIG. 7, the mounting surface 10a may be located in the bottom of a substrate recess 13 formed in the mounting substrate 10, and the outer periphery 10b may be located outside the substrate recess 13 and may not be on the same plane as the mounting surface 10a.

In the third embodiment, the side wall surface 13b of the substrate recess 13 and the side surface 24 are faced each other, and a gap between the side wall surface 13b and the side surface 24 forms the second sub gap 83. The second ceiling surface 13a, which is the top surface of the second sub gap 83, is formed in a planar shape parallel to the mounting surface 10a of the mounting substrate 10. The gas layer 70 is formed in the second sub gap 83.

Even in the third embodiment, the position, where the light transmitting member 40 and the mounting substrate 10 are bonded, is located closer to the mounting substrate surface 10a of the mounting substrate 10 (lower side in FIG. 1) than the active layer 92b of the light emitting element 20 in the direction Y perpendicular to the mounting surface 10a of the mounting substrate 10. In other words, the light transmitting member bonding layer 50 is located closer to the mounting surface 10a of the mounting substrate 10 than the first sub gap 82. Furthermore, the light transmitting member bonding layer 50 is located closer to the mounting surface 10a of the mounting substrate 10 than the active layer 92b. In the third embodiment, same symbols are given to the configuration corresponding to that of the first embodiment, and repeated explanation is omitted. In the third embodiment, the same operation and effect are obtained as in the first embodiment.

### Fourth Embodiment

In the first embodiment above, the light transmitting member 40 has the first recess 42 and the second recess 43, and the gap facing the side surface 24 of the light emitting element 20 has the first sub gap 82 and the second sub gap 83.

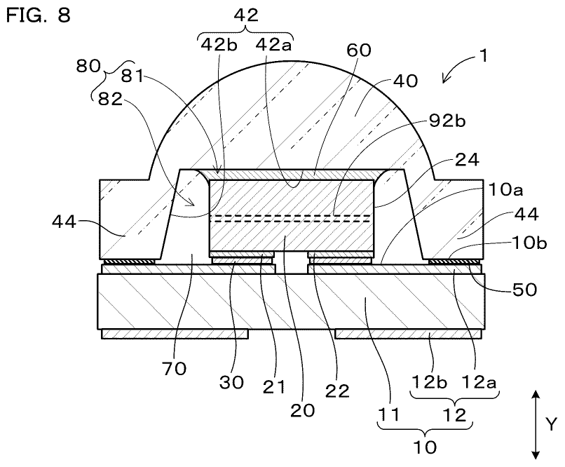

Alternatively, as shown in FIG. 8, the light transmitting member 40 may be provided only with the first recess 42, and the gap facing the side surface 24 may have only the first sub gap 82. That is, the distance H2 of the first sub gap 82 is larger than that of the first embodiment and is equal to the distance H3 of the second sub gap 83 in the first embodiment.

In this configuration, when the contact angle θ1 of the inert compound 60 dropped onto the main surface of element 23 at a temperature of 25° C. is within the above angle range, the inert compound 60 is held in the main gap 81 by capillary action. However, the inert compound 60 is placed in contact with a part of the side surface of element 24.

The present disclosure is not limited to the above embodiments, but can be applied to various embodiments to the extent not departing from the gist thereof.

What is claimed is:

1. A light emitting device comprising:
a mounting substrate having a mounting surface;
an ultraviolet light emitting element disposed on the mounting surface of the mounting substrate and having a main surface facing opposite the mounting surface and a side surface adjacent to the main surface of the light emitting element;
a light transmitting member disposed on the mounting surface of the mounting substrate and forming a housing space for housing the light emitting element in a gap with the mounting surface of the mounting substrate;
an inert compound being liquid at normal temperature and pressure and filled in at least a main gap between the main surface of the light emitting element and the light transmitting member in the housing space; and
a gas layer formed in a gap facing the side surface of the light emitting element in the housing space, wherein
the inert compound has a contact angle of 10° to 30° with respect to the main surface of the light emitting element at a temperature of 25° C.

2. The light emitting device according to claim 1, wherein the inert compound has a viscosity of 0.01 Pa·s to 50 Pa·s at a temperature of 25° C.

3. The light emitting device according to claim 1, wherein the main surface of the light emitting element has an arithmetic mean roughness Ra of 0.1 nm to 100,000 nm.

4. The light emitting device according to claim 1, wherein the inert compound is disposed in contact with at least a part of the side surface of the light emitting element in the housing space, and
the inert compound has a contact angle of 10° to 30° with respect to the side surface of the light emitting element at a temperature of 25° C.

5. The light emitting device according to claim 4, wherein the side surface of the light emitting element has an arithmetic mean roughness Ra of 0.1 nm to 100,000 nm.

6. The light emitting device according to claim 1, wherein the inert compound has a boiling point of 150° C. or higher.

7. The light emitting device according to claim 6, wherein the light emitting element during operation is configured to have a junction temperature of 150° C. or lower.

8. The light emitting device according to claim 1, wherein the inert compound has a transmittance of 50% or more for ultraviolet light with an emission wavelength.

9. The light emitting device according to claim 1, wherein the inert compound includes a fluoride compound.

10. The light emitting device according to claim 1, wherein the light emitting element constitutes a flip chip type which outputs light from a back surface of an element substrate included in the light emitting element, and
the main surface of the light emitting element is located on the back surface with respect to a surface on which a semiconductor layer is formed of the element substrate.

11. The light emitting device according to claim 1, wherein the main gap has a distance of 0.1 μm to 500 μm.
